(19) United States
(12) Patent Application Publication
(10) Pub. No.: US 2025/0379569 A1
(43) Pub. Date: Dec. 11, 2025

(54) PHASE INTERPOLATION CIRCUIT

(71) Applicant: Realtek Semiconductor Corp., HsinChu (TW)

(72) Inventor: Tsung-Han Tsai, HsinChu (TW)

(73) Assignee: Realtek Semiconductor Corp., HsinChu (TW)

(21) Appl. No.: 19/228,792

(22) Filed: Jun. 5, 2025

(30) Foreign Application Priority Data
Jun. 7, 2024 (TW) 113121181

(51) Int. Cl. H03K 5/135; H03K 5/08

(52) U.S. Cl. CPC H03K 5/135; H03K 5/08

(57) ABSTRACT

A phase interpolation circuit for generating a phase interpolation signal, comprising: a capacitor; a first charging circuit for selectively charging the capacitor according to a first clock signal and a first weighting control code; a second charging circuit for selectively charging the capacitor according to a second clock signal and a second weighting control code; a first discharge circuit for selectively discharging the capacitor according to the first clock signal and a third weighting control code; and a second discharge circuit for selectively discharging the capacitor according to the second clock signal and a fourth weighting control code. The first, second, third and fourth weighting control codes respectively control the weightings of the first clock signal and the second clock signal in the phase interpolation signal.

### BACKGROUND OF THE INVENTION

### 1. Field of the Invention

The present invention relates to a phase interpolation circuit, and particularly relates to a phase interpolation circuit which can generate a phase interpolation signal using a simple structure.

### 2. Description of the Prior Art

In the current electronics industry, phase interpolation circuits are circuits which are frequently used to interpolate required phase interpolation signals. However, conventional phase interpolation circuits usually have more complex circuit structures and operations, thus have poor linearity, consume more power, and have longer delays.

Therefore, a new phase interpolation circuit is needed.

### SUMMARY OF THE INVENTION

One objective of the present invention is to provide a phase interpolation circuit that can improve linearity, circuit power consumption and signal delay.

One embodiment of the present invention provides a phase interpolation circuit, configured to generate a phase interpolation signal, comprising: a capacitor; a first charging circuit, coupled to the capacitor, configured to selectively charge the capacitor according to a first clock signal and a first weighting control code, wherein the first weighting control code determines a first weighting of the first clock signal in the phase interpolation signal; a second charging circuit, coupled to the capacitor, configured to selectively charge the capacitor according to a second clock signal and a second weighting control code, wherein the second weighting control code determines a second weighting of the second clock signal in the phase interpolation signal; a first discharging circuit, coupled to the capacitor, configured to selectively discharge the capacitor according to the first clock signal and a third weighting control code, wherein the third weighting control code determines a third weighting of the first clock signal in the phase interpolation signal; and a second discharging circuit, coupled to the capacitor, configured to selectively discharge the capacitor according to the second clock signal and a fourth weighting control code, wherein the fourth weighting control code determines a fourth weighting of the second clock signal in the phase interpolation signal.

Another embodiment of the present invention provides a phase interpolation circuit, configured to generate a phase interpolation signal, comprising: a capacitor; a first charging circuit, coupled to the capacitor, configured to selectively charge the capacitor according to a first clock signal and a first weighting control code; a second charging circuit, coupled to the capacitor, configured to selectively charge the capacitor according to a second clock signal and a second weighting control code; a first discharging circuit, coupled to the capacitor, configured to selectively discharge the capacitor according to the first clock signal and a third weighting control code; and a second discharging circuit, coupled to the capacitor, configured to selectively discharge the capacitor according to the second clock signal and a fourth weighting control code; wherein the first charging circuit, the second charging circuit, the first discharging circuit and the second discharging circuit respectively comprises switches which are serially connected; wherein the first weighting control code, the second weighting control code, the third weighting control code and the fourth weighting control code respectively determines numbers of the switch, which turn on, of the first charging circuit, the second charging circuit, the first discharging circuit, the second discharging circuit.

In view of embodiments, a simple circuit can be used to generate a phase interpolation signal, which can increase the linearity of the phase interpolation signal and improve circuit power consumption and signal delay.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a block diagram illustrating a phase interpolation circuit according to one embodiment of the present invention.

FIG. 2 is a circuit diagram illustrating a phase interpolation circuit according to one embodiment of the present invention.

FIG. 3 is a circuit diagram illustrating the first charging circuit with N=3, according to one embodiment of the present invention.

FIG. 4 and FIG. 5 are schematic diagrams illustrating operations of the phase interpolation circuit in FIG. 2, according to embodiments of the present invention.

FIG. 6 is a schematic diagram illustrating an interpolation clock signal, according to one embodiment of the present invention.

FIG. 7 is a schematic diagram illustrating the steps of generating weighting control codes, according to one embodiment of the present invention.

### DETAILED DESCRIPTION

In the following descriptions, several embodiments are provided to explain the concept of the present application. The term “first”, “second”, “third” in following descriptions are only for the purpose of distinguishing different one elements, and do not mean the sequence of the elements. For example, a first device and a second device only mean these devices can have the same structure but are different devices.

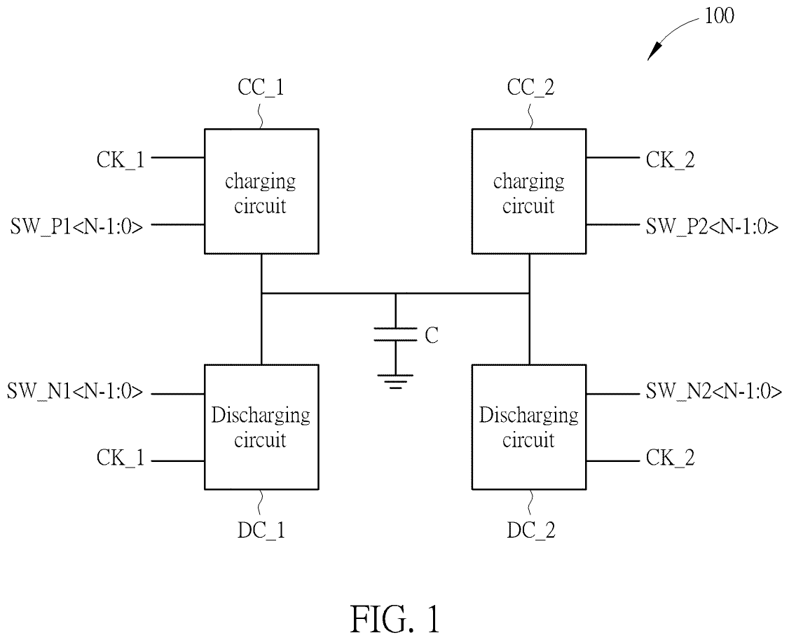

FIG. 1 is a block diagram illustrating a phase interpolation circuit 100 according to one embodiment of the present invention. As shown in FIG. 1, the phase interpolation circuit 100 is configured to generate an interpolation clock signal and comprises a capacitor C, a first charging circuit CC_1, a second charging circuit CC_2, a first discharging circuit DC_1 and a second charging circuit DC_2. The voltage of the capacitor C can be used to generate an interpolation clock signal. In the following embodiments, the voltages of the capacitor C are directly used as the interpolation clock signal. The first charging circuit CC_1 is coupled to the capacitor C and configured to selectively charge the capacitor C according to a first clock signal CK_1 and a first weighting control code SW_P1<N-1:0>. The first weighting control code SW_P1< N-1:0> determines the first weighting of the first clock signal CK_1 in the interpolation clock signal. The second charging circuit CC_2 is coupled to the capacitor C and configured to selectively charge the capacitor C according to a second clock signal CK_2 and a second weighting control code SW_P2<N-1:0>. The second weighting control code SW_P2<N-1:0> determines a second weighting of the second clock signal CK_2 in the interpolation clock signal.

The first discharging circuit DC_1 is coupled to the capacitor C and is configured to selectively discharge the capacitor C according to the first clock signal CK_1 and a third weighting control code SW_N1<N-1:0>. The third weighting control code SW_N1<N-1:0> determines a third weighting of the first clock signal CK_1 in the interpolation clock signal. The second discharging circuit CC_2 is coupled to the capacitor C and is configured to selectively discharge the capacitor C according to the second clock signal CK_2 and a fourth weighting control code SW_N2<N-1:0>. The fourth weighting control code SW_N2<N-1:0> determines a fourth weighting of the second clock signal CK_2 in the interpolation clock signal.

In more detail, the first charging circuit CC_1 is connected in series (serially connected) with the first discharging circuit DC_1, and the second charging circuit CC_2 is connected in series with the second discharging circuit DC_2. A first terminal of the capacitor C is coupled to the coupling point of the first charging circuit CC_1 and the first discharging circuit DC_1, and a second terminal of the capacitor C is coupled to the coupling point of the second charging circuit CC_2 and the second discharging circuit DC 2.

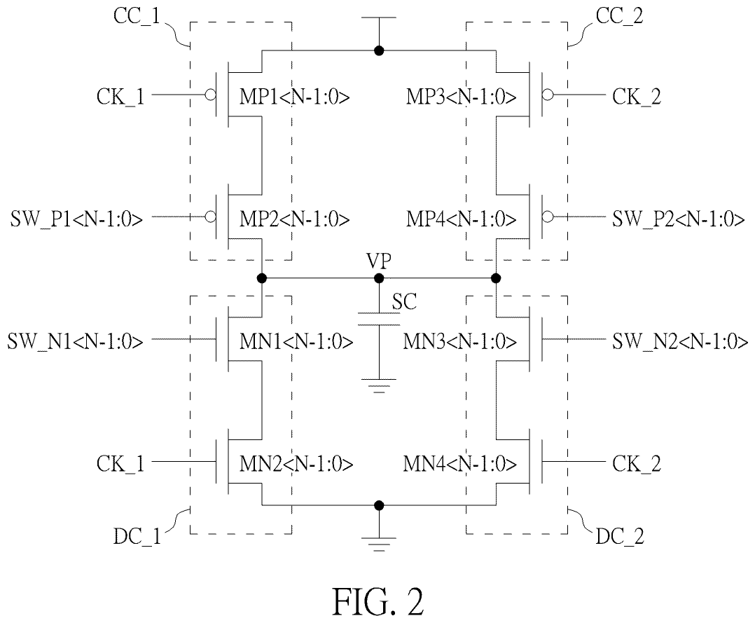

The charging circuits and discharging circuits shown in FIG. 1 may have various circuit architectures. FIG. 2 is a circuit diagram illustrating a phase interpolation circuit according to one embodiment of the present invention. As shown in FIG. 2, the first charging circuit CC_1 comprises a first type one clock switch group MP1<N-1:0> and a first type one weighting switch group MP2<N-1:0>. The first type one clock switch group MP1<N-1:0>comprises at least one first type one clock switch, and the first type one clock switch turns on or turns off at the same time according to the first clock signal. The first type one weighting switch group MP2<N-1:0>comprises at least one first type one weighting switch, and the first type one weighting switch respectively turns on or turns off according to the first weighting control code.

In one embodiment, the first type one clock switch and the first type one weighting switch are PMOSs, but they can also be other transistors with the same function. N is a positive integer not less than 1, which represents the number of switches in the switch group. For example, if N=1, the first type one clock switch group MP1<0:0> and the first type one weighting switch group MP2<0:0> respectively comprise a first type one clock switch and a first type one weighting switch. If N=4, the first type one clock switch group MP1<3:0> and the first type one weighting switch group MP2<3:0> respectively comprise three first type one clock switches and three first type One weighting switch.

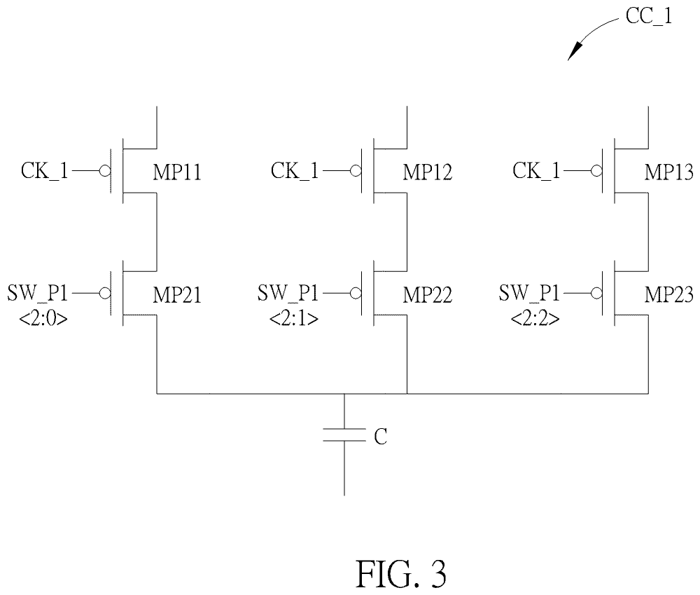

FIG. 3 is a circuit diagram illustrating the first charging circuit with N=3, according to one embodiment of the present invention. As shown in FIG. 3, the first charging circuit CC_1 comprises three first type one clock switches MP11, MP12, and MP13 and three first type one weighting switches MP21, MP22, and MP23. Each of the first type one clock switches MP11, MP12, MP13 is connected in series with a different one of the first type one weighting switch MP21, MP22, MP23. For example, as shown in FIG. 3, the first type one clock switch MP11 is connected in series with the first type one weighting switch MP21, and the first type one clock switch MP12 is connected in series with the first type one weighting switch MP22. The control terminals (such as gates) of the first type one clock switches MP11, MP12, and MP13 all receive the first clock signal CK_1, and therefore are simultaneously controlled by the first clock signal CK_1 to turn on or turn off. The control terminals of the first type one weighting switches MP21, MP22 and MP23 respectively receive different first weighting control codes SW_P1<2:0>, SW_P1<2:1> and SW_P1 <2:2>, so they turn or turn off respectively.

Please return to FIG. 2. The second charging circuit CC_2 comprises a second type one clock switch group MP3<N-1:0> and a second type one weighting switch group MP4<N-1:0>. The second type one clock switch group MP3 <N-1:0> comprises at least one second type one clock switch, and the second type one clock switch turns on or turns off at the same time according to the second clock signal CK_2. The second type one weighting switch group MP4<N-1:0> comprises at least one second type one weighting switch. The second type one weighting switch turns on or turns off respectively according to the second weighting control code SW_P2<N-1:0>. In one embodiment, both the second type one clock switch and the second type one weighting switch are PMOSs, but they can also be other transistors with the same function. In one embodiment, each second type one clock switch is connected in series with a different second type one weighting switch.

In the embodiment of FIG. 2, the first discharging circuit DC_1 comprises a first type two weighting switch group MN1<N-1:0> and a first type two clock switch group MN2<N-1:0>. The first type two clock switch group MN2<N-1:0> comprises at least one first type two clock switch, and the first type two clock switches turn on or turn off at the same time according to the first clock signal CK_1. The first type two weighting switch group MN1<N-1:0> comprises at least one first type two weighting switch. The first type two weighting switch turns on or turns off respectively according to the third weighting control code SW_N1<N-1:0>.

The second discharging circuit DC 2 comprises a second type two weighting switch group MN3<N-1:0> and a second type two clock switch group MN4<N-1:0>. The second type two clock switch group MN4<N-1:0> comprises at least one second type two clock switch, and the second type two clock switches turn on or turn off at the same time according to the second clock signal CK_2. The second type two weighting switch group MN3<N-1:0> comprises at least one second type two weighting switch. The second type two weighting switch turns on turns off respectively according to the fourth weighting control code SW_N2<N-1:0>. In one embodiment, the first type two clock switch, the first type two weighting switch, the second type two clock switch and the second type two weighting switch are all NMOSs. Each first type two clock switch is connected in series with a different first type two weighting switch, and each second type two clock switch is connected in series with a different second type two weighting switch. The detail circuit structures of the second charging circuit CC_2, the first discharging circuit DC_1 and the second discharging circuit DC_2 can be deduced from the descriptions of FIG. 2, the first charging circuit CC_1 and FIG. 3, thus are omitted for brevity here.

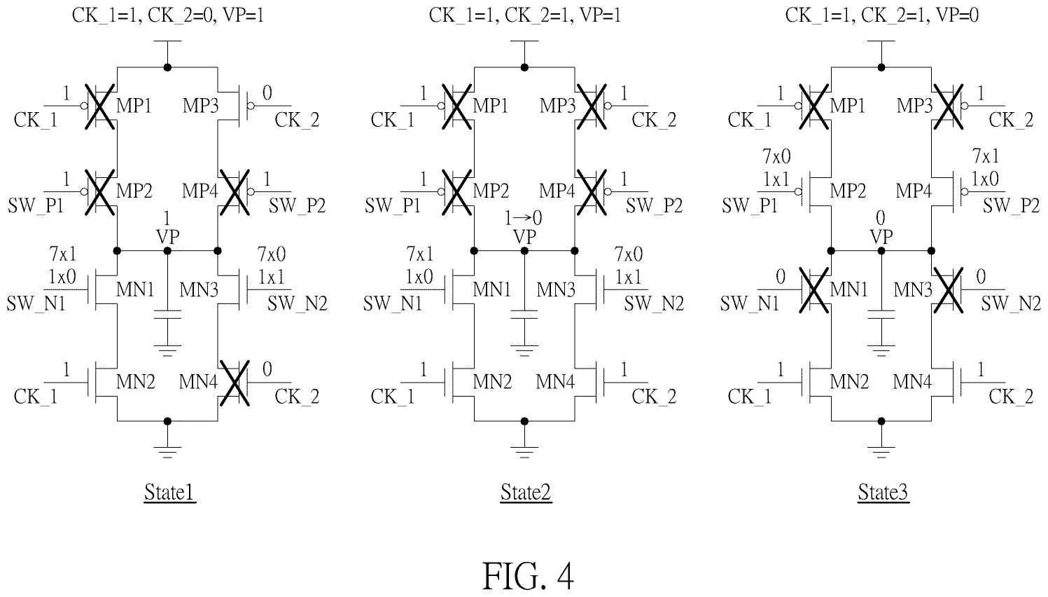

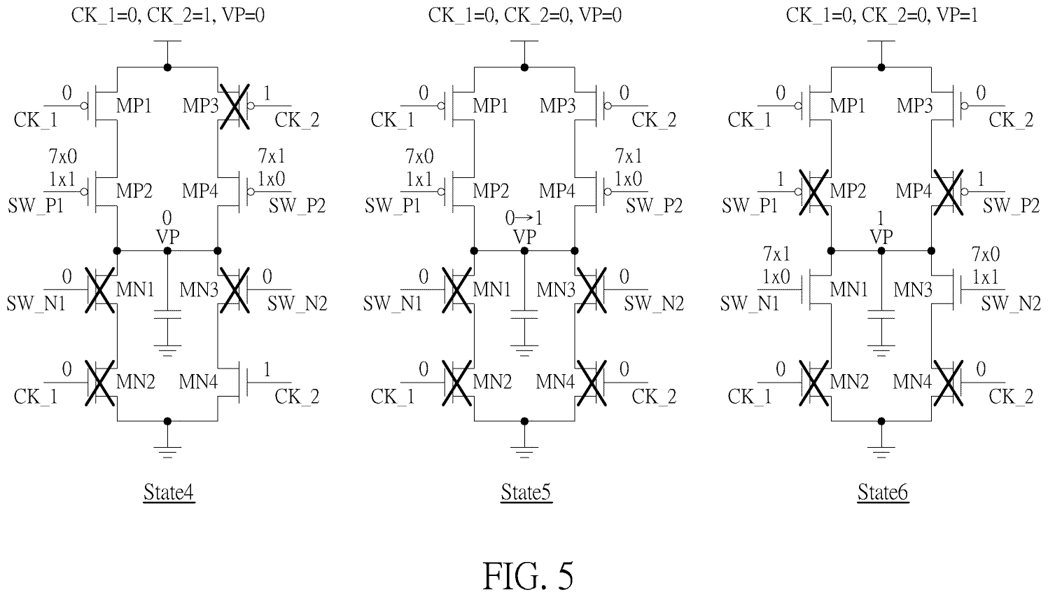

FIG. 4 and FIG. 5 are schematic diagrams illustrating operations of the phase interpolation circuit in FIG. 2, according to embodiments of the present invention. In FIG. 4 and FIG. 5, VP means the voltage of capacitor C. Please also note that for the convenience of explanation, in FIG. 4 and FIG. 5, some of the labels shown in FIG. 2 are omitted, and the first weighting control code SW_P1<N-1:0>, the second weighting control code SW_P2<N-1:0>, the third weighting control code SW_N1<N-1:0> and the fourth weighting control code SW_N2<N-1:0> are respectively abbreviated as the first weighting control code SW_P1 the second weighting control code SW_P2, the third weighting control code SW_N1 and the fourth weighting control code SW_N2. The first type one clock switch group MP1<N-1:0>, the first type one weighting switch group MP2<N-1:0>, the second type one clock switch group MP3<N-1:0>, the second type one weighting switch group MP4<N-1:0>, the first type two weighting switch group MN1<N-1:0>, the first type one two clock switch group MN2<N-1: 0>, the second type two weighting switch group MN3<N-1:0> and the second type two clock switch group MN4<N-1:0> are respectively abbreviated as the first type one clock switch group MP1, the first type one weighting switch group MP2, the second type one clock switch group MP3, the second type one weighting switch group MP4, the first type two weighting switch group MN1, the first type two clock switch group MN2, the second type two weighting switch group MN3 and the second type two clock switch group MN4. The present invention can be better understood by referring to FIG. 2, FIG. 4 and FIG. 5 at the same time.

In one embodiment, in the initial state (not shown), the first clock signal CK_1 and the second clock signal CK_2 are both 0, and the first weighting control code SW_P1, the second weighting control code SW_P2 are both 1, therefore the first charging circuit CC_1, the second charging circuit CC_2, the first discharging circuit DC_1 and the second discharging circuit DC_2 all turn off. At this time, the capacitor C is fully charged, that is, the voltage VP is 1. In state 1 in FIG. 4, the first clock signal CK_1 is 1 and the second clock signal CK_2 is 0, the first weighting control code SW_P1 and the second weighting control code SW_P2 are both 1. The third weighting control code SW_N1 causes 7 switches in the first type two weighting switch group MN1 to turn on and 1 switch in the first type two weighting switch group MN1 to turn off. The fourth weighting control code SW_N2 causes 7 switches in the second type two weighting switch group MN3 to turn off and 1 switch in the second type two weighting switch group MN3 to turn on. Therefore, in state 1, the first discharging circuit DC_1 turns on and the other charging circuits, discharging circuits turn off, thus causing the capacitor C to discharge.

In state 2 of FIG. 4, the first clock signal CK_1 and the second clock signal CK_2 are both 1, the first weighting control code SW_P1 and the second weighting control code SW_P2 are both 1. The third weighting control code SW_N1 causes 7 switches in the first type two weighting switch group MN1 to turn off and 1 switch in the first type two weighting switch group MN1 to turn on. The fourth weighting control code SW_N2 causes 7 switches in the second type two weighting switch group MN3 to turn off and 1 switch in the second type two weighting switch group MN3 to turn on. Therefore, in state 2, the first discharging circuit DC_1 and the second discharging circuit DC_2 turn on and the other charging circuits turn off, so the capacitor C is discharged and its value changes from 1 to 0.

In state 3 of FIG. 4, the first clock signal CK_1 and the second clock signal CK_2 are both 1. The first weighting control code SW_P1 turns on 7 switches and turns off 1 switch in the first type one weighting switch group MP2. The second weighting control code SW_P2 turns off 7 switches and turns on 1 switch in the second type one weighting switch group MP4. The third weighting control code SW_N1 and the fourth weighting control code SW_N2 are both 0. Therefore, in state 3, the capacitor C has been discharged and becomes 0 and all charging circuits and discharging circuits turn off.

In state 4 of FIG. 5, the first charging circuit CC_1 turns on and the other charging circuits, discharging circuits turn off, so the capacitor C starts to be charged. In state 5 in FIG. 5, the first charging circuit CC_1 and the second charging circuit CC_2 both turn on and the discharging circuit turns off, so the capacitor C is still charged so that its value changes from 0 to 1. In state 6 in FIG. 5, the capacitor C is completely charged, and all charging circuits, discharging circuits turn off. The operations of the phase interpolation circuit in FIG. 5 are the same as which in FIG. 4. Therefore, its detail operation can be acquired from the labels in FIG. 5 and the descriptions in FIG. 4, thus are omitted for brevity here.

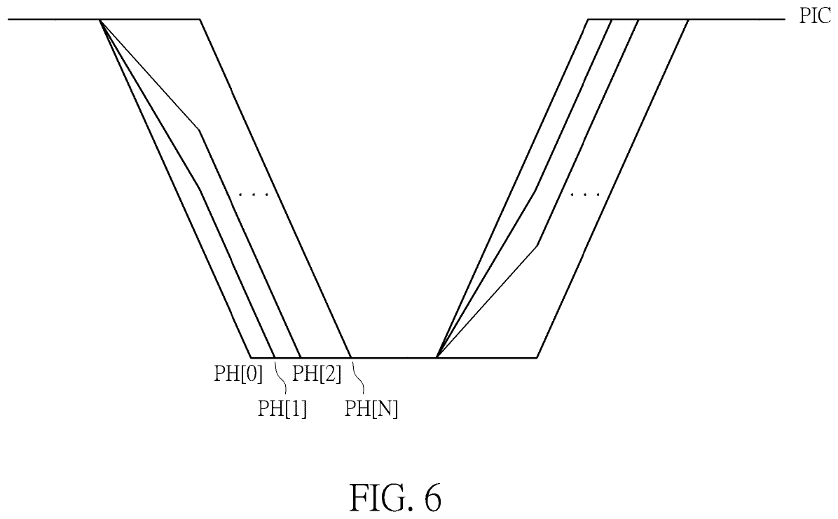

Through the actions of FIG. 4 and FIG. 5, the voltage VP can be changed to generate an interpolation clock signal, and the number the weighting switches which turn on can be changed according to the selected phase (i.e., setting the weighting control code). By this way, the charging speed and discharging speed of the capacitor C are changed (that is, change the weighting of the first clock signal CK_1 and the second clock signal CK_2). FIG. 6 is a schematic diagram illustrating an interpolation clock signal, according to one embodiment of the present invention. As shown in FIG. 6, the interpolation clock signal PIC can have different waveforms at different phases PH[0], PH[1], PH[2] . . . due to different charging speeds and discharging speeds. In the embodiments of FIG. 4 and FIG. 5, the phase PH[1] is selected. In phase PH[1], the number the weighting switch which turns on is 1 or 7. In other phases, due to different weighting control codes, the number of the weighting switches which turn on will also vary.

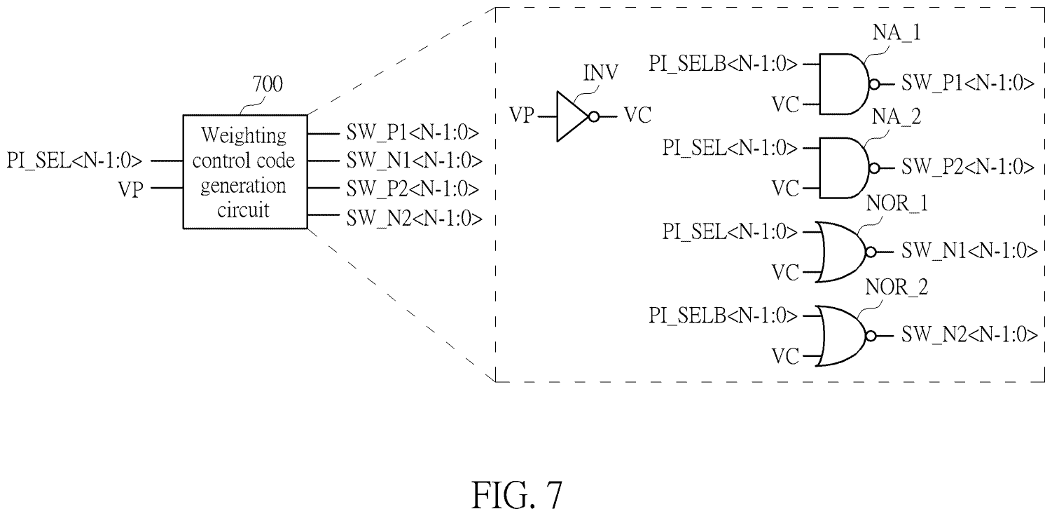

As mentioned above, the phase can be selected by changing the weighting control code, and the weighting control code can be generated in a variety of ways. FIG. 7 is a schematic diagram illustrating the steps of generating weighting control codes, according to one embodiment of the present invention. In the embodiment of FIG. 7, the phase interpolation circuit comprises a weighting control code generation circuit 700, which comprises an inverter INV, NAND gates NA_1 and NA_2, and NOR gates NOR_1 and NOR_2. As shown in FIG. 7, the weighting control code generation circuit 700 receives a phase selection code P_SEL<N-1:0> to determine the aforementioned first weighting control code SW_P1<N-1:0>, the second weighting control code SW_P2<N-1:0>, the third weighting control code SW_N1<N-1:0> and the fourth weighting control code SW_N2<N-1:0> then determine the first weighting, the second weighting, the third weighting and the fourth weighting.

In detail, the inverter INV is used to receive the voltage VP to generate the inverted voltage VC. The NAND gates NA_1 and NA_2 and the NOR gates NOR_1 and NOR_2 respectively receive the phase selection code P_SEL<N-1:0> or its inverted code P_SELB<N-1:0> and an inverted voltage VC to generate the first weighting control code SW_P1<N-1:0>, the second weighting control code SW_P2<N-1:0>, the third weighting Control code SW_N1<N-1:0> and the fourth weighting control code SW_N2<N-1:0>. However, please note that the weighting control code of the present invention is not limited to being generated using the method shown in FIG. 7.

In view of embodiments, a simple circuit can be used to generate a phase interpolation signal, which can increase the linearity of the phase interpolation signal and improve circuit power consumption and signal delay.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A phase interpolation circuit, configured to generate a phase interpolation signal, comprising:
a capacitor;
a first charging circuit, coupled to the capacitor, configured to selectively charge the capacitor according to a first clock signal and a first weighting control code, wherein the first weighting control code determines a first weighting of the first clock signal in the phase interpolation signal;
a second charging circuit, coupled to the capacitor, configured to selectively charge the capacitor according to a second clock signal and a second weighting control code, wherein the second weighting control code determines a second weighting of the second clock signal in the phase interpolation signal;
a first discharging circuit, coupled to the capacitor, configured to selectively discharge the capacitor according to the first clock signal and a third weighting control code, wherein the third weighting control code determines a third weighting of the first clock signal in the phase interpolation signal; and
a second discharging circuit, coupled to the capacitor, configured to selectively discharge the capacitor according to the second clock signal and a fourth weighting control code, wherein the fourth weighting control code determines a fourth weighting of the second clock signal in the phase interpolation signal.

2. The phase interpolation circuit of claim 1,
wherein the first charging circuit comprises:
a first type one clock switch group, comprising at least one first type one clock switch, wherein the first type one clock switch simultaneously turn on or turn off according to the first clock signal;
a first type one weighting switch group, comprising at least one first type one weighting switch, wherein the first type one weighting switch simultaneously turn on or turn off according to the first weighting control code;
wherein the second charging circuit comprises:
a second type one clock switch group, comprising at least one second type one clock switch, wherein the second type one clock switch simultaneously turn on or turn off according to the second clock signal;
a second type one weighting switch group, comprising at least one second type one weighting switch, wherein the second type one weighting switch simultaneously turn on or turn off according to the second weighting control code.

3. The phase interpolation circuit of claim 2, wherein first type one clock switch, the first type one weighting switch, the second type one clock switch and the second type one weighting switch are PMOSS.

4. The phase interpolation circuit of claim 2, wherein each one of the first type one clock switch is serially connected to a different one of the first type one weighting switch, and each one of the second type one clock switch is serially connected to a different one of the second type one weighting switch.

5. The phase interpolation circuit of claim 1,
wherein the first discharging circuit comprises:
a first type two clock switch group, comprising at least one first type two clock switch, wherein the first type two clock switch simultaneously turn on or turn off according to the first clock signal;
a first type two weighting switch group, comprising at least one first type two weighting switch, wherein the first type two weighting switch simultaneously turn on or turn off according to the third weighting control code;
wherein the second discharging circuit comprises:
a second type two clock switch group, comprising at least one second type two clock switch, wherein the second type two clock switch simultaneously turn on or turn off according to the second clock signal;
a second type two weighting switch group, comprising at least one second type two weighting switch, wherein the second type two weighting switch simultaneously turn on or turn off according to the fourth weighting control code.

6. The phase interpolation circuit of claim 5, wherein first type two clock switch, the first type two weighting switch, the second type two clock switch and the second type two weighting switch are NMOSs.

7. The phase interpolation circuit of claim 5, wherein each one of the first type two clock switch is serially connected to a different one of the first type two weighting switch, and each one of the second type two clock switch is serially connected to a different one of the second type two weighting switch.

8. The phase interpolation circuit of claim 1,
wherein the first charging circuit and the first discharging circuit are serially connected, the second charging circuit and the second discharging circuit are serially connected;
wherein a first terminal of the capacitor is coupled to a coupling point of the first charging circuit and the first discharging circuit;
wherein a second terminal of the capacitor is coupled to a coupling point of the second charging circuit and the second discharging circuit.

9. The phase interpolation circuit of claim 1, wherein the phase interpolation circuit further receives a phase selection code for determining the first weighting, the second weighting, the third weighting and the fourth weighting.

10. A phase interpolation circuit, configured to generate a phase interpolation signal, comprising:
a capacitor;
a first charging circuit, coupled to the capacitor, configured to selectively charge the capacitor according to a first clock signal and a first weighting control code;
a second charging circuit, coupled to the capacitor, configured to selectively charge the capacitor according to a second clock signal and a second weighting control code;
a first discharging circuit, coupled to the capacitor, configured to selectively discharge the capacitor according to the first clock signal and a third weighting control code; and
a second discharging circuit, coupled to the capacitor, configured to selectively discharge the capacitor according to the second clock signal and a fourth weighting control code;
wherein the first charging circuit, the second charging circuit, the first discharging circuit and the second discharging circuit respectively comprises switches which are serially connected;
wherein the first weighting control code, the second weighting control code, the third weighting control code and the fourth weighting control code respectively determines numbers of the switch, which turn on, of the first charging circuit, the second charging circuit, the first discharging circuit, the second discharging circuit.

11. The phase interpolation circuit of claim 10,
wherein the first charging circuit comprises:
a first type one clock switch group, comprising at least one first type one clock switch, wherein the first type one clock switch simultaneously turn on or turn off according to the first clock signal;
a first type one weighting switch group, comprising at least one first type one weighting switch, wherein the first type one weighting switch simultaneously turn on or turn off according to the first weighting control code;
wherein the second charging circuit comprises:
a second type one clock switch group, comprising at least one second type one clock switch, wherein the second type one clock switch simultaneously turn on or turn off according to the second clock signal;
a second type one weighting switch group, comprising at least one second type one weighting switch, wherein the second type one weighting switch simultaneously turn on or turn off according to the second weighting control code.

12. The phase interpolation circuit of claim 11, wherein first type one clock switch, the first type one weighting switch, the second type one clock switch and the second type one weighting switch are PMOSs.

13. The phase interpolation circuit of claim 11, wherein each one of the first type one clock switch is serially connected to a different one of the first type one weighting switch, and each one of the second type one clock switch is serially connected to a different one of the second type one weighting switch.

14. The phase interpolation circuit of claim 10,
wherein the first discharging circuit comprises:
a first type two clock switch group, comprising at least one first type two clock switch, wherein the first type two clock switch simultaneously turn on or turn off according to the first clock signal;
a first type two weighting switch group, comprising at least one first type two weighting switch, wherein the first type two weighting switch simultaneously turn on or turn off according to the third weighting control code;
wherein the second discharging circuit comprises:
a second type two clock switch group, comprising at least one second type two clock switch, wherein the second type two clock switch simultaneously turn on or turn off according to the second clock signal;
a second type two weighting switch group, comprising at least one second type two weighting switch, wherein the second type two weighting switch simultaneously turn on or turn off according to the fourth weighting control code.

15. The phase interpolation circuit of claim 14, wherein first type two clock switch, the first type two weighting switch, the second type two clock switch and the second type two weighting switch are NMOSs.

16. The phase interpolation circuit of claim 14, wherein each one of the first type two clock switch is serially connected to a different one of the first type two weighting switch, and each one of the second type two clock switch is serially connected to a different one of the second type two weighting switch.

17. The phase interpolation circuit of claim 10,
wherein the first charging circuit and the first discharging circuit are serially connected, the second charging circuit and the second discharging circuit are serially connected;
wherein a first terminal of the capacitor is coupled to a coupling point of the first charging circuit and the first discharging circuit;
wherein a second terminal of the capacitor is coupled to a coupling point of the second charging circuit and the second discharging circuit.

18. The phase interpolation circuit of claim 10, wherein the phase interpolation circuit further receives a phase selection code for determining the first weighting, the second weighting, the third weighting and the fourth weighting.
